(19) United States
(12) Patent Application Publication
(10) Pub. No.: US 2025/0216319 A1
(43) Pub. Date: Jul. 3, 2025

(54) TEST EQUIPMENT AND AIR CURTAIN STRUCTURE THEREOF

(71) Applicant: SILICONWARE PRECISION INDUSTRIES CO., LTD., Taichung City (TW)

(72) Inventors: Hsun-Yung CHO, Taichung City (TW); Ming-Jen LIN, Taichung City (TW); Chun-Sung HUANG, Taichung City (TW); Ling-Fei CHENG, Taichung City (TW); Hsi-Chih CHEN, Taichung City (TW)

(21) Appl. No.: 19/007,826

(22) Filed: Jan. 2, 2025

(30) Foreign Application Priority Data
Jan. 2, 2024 (TW) 113100101

(51) Int. Cl. G01N 17/00; F24F 9/00

(52) U.S. Cl. CPC G01N 17/002; F24F 9/00

(57) ABSTRACT

A test equipment is provided, which includes a cabin for providing a low-temperature testing environment for elements under test, and an air curtain structure surrounding the cabin to send dry air toward the cabin. The air curtain structure includes a ring body and a plurality of openings disposedinside the ring body, so that the ring body can send dry air toward the cabin through the plurality of openings, thereby reducing the ambient humidity and preventing condensation water dripping from causing the test equipment damage.

### CROSS-REFERENCE TO RELATED APPLICATIONS

The present application is based upon and claims the right of priority to TW patent application Ser. No. 11/310,0101, filed Jan. 2, 2024, the disclosure of which is hereby incorporated by reference herein in its entirety for all purposes

### BACKGROUND

### 1. Technical Field

The present disclosure relates to a test equipment, and more particularly, to a test equipment applied to a semiconductor device and an air curtain structure thereof.

### 2. Description of Related Art

A traditional electronic element with a plurality of contacts requires processes such as die bonding, wire bonding, and encapsulating, and then is cut into an independent electronic element through a cutting and molding process. Besides, in order to ensure the quality of electronic elements, packaging manufacturers need to conduct testing operations on electronic elements through test equipment to eliminate defective products.

In addition, electronic elements may be in extremely low or high temperature environments during actual use. Therefore, when test equipment performs electrical testing on electronic elements, the electronic elements must be simulated to be tested in low or high temperature environments for actual uses in the future.

To this end, in view of current mainstream 3C electronic products (such as mobile phones/cameras) that need to adapt to extremely low temperature environments and keep work, packaging manufacturers must put the electronic element into low temperature test machines to simulate/test ultra-low temperature environments, such as still working under a test standard of minus 55˜65 degree, thus packaging industries have developed a test machine 1 as shown in FIG. 1, wherein the test machine 1 comprises: a cabin 11, a robotic arm 12 for picking electronic elements, a pair of test slot base bodies 13 for testing electronic elements and a circuit board 14 for receiving test signals.

However, the aforementioned cabin 11 has a sealed space, internal temperature must be simulated as in an ultra-low temperature state, while outside the cabin 11 is at normal temperature. Since the temperature difference between the two sides is too large, so condensation water w will be formed on a bottom surface of the cabin 11. If condensation water w dropped onto the circuit board 14, it might cause a short circuit or even damage the circuit board 14, so industries currently heat up the outside of the cabin 11 at a specific operating time (such as four hours) by manual methods, such that condensation water w evaporates and be removed by manual wiping.

However, the aforementioned manual methods not only waste manpower but also require time to heat up and remove condensation water. Furthermore, it still exists the possibility for condensation water dropped onto the circuit board due to improper manual operations. Therefore, how to solve the aforementioned shortcomings has become an urgent issue to be addressed at present.

### SUMMARY

In view of the various shortcomings of the prior art, the present disclosure provides a test equipment comprises: a cabin providing a low-temperature testing environment for an element under test; a pick-and-place device used to move the element under test into the cabin; a test base body connected to the cabin for testing the element under test; an electronic carrier connected to the test base body for receiving test information; and an air curtain structure surrounding the cabin to output fluid toward the cabin.

In the aforementioned test equipment, the pick-and-place device is a robotic arm.

In the aforementioned test equipment, the element under test is an electronic elements.

In the aforementioned test equipment, the air curtain structure is fixed to a side of the test base body or an outer surface of the cabin.

The present disclosure further provides an air curtain structure, applied to a test equipment with a cabin for providing a low-temperature testing environment for an element under test, the air curtain structure comprises: a ring body surrounding the cabin, and the ring body being hollow for fluid flowing therethrough; and a plurality of openings formed inside the ring body for the fluid being output from inside the ring body toward the cabin to outside.

In the aforementioned air curtain structure, a plurality of pipelines are connected to the outside of the ring body to allow providing fluid to the ring body from outside.

In the aforementioned air curtain structure, a direction of the plurality of openings is tilting upward to output the fluid.

As can be understood from the above, in the test equipment of the present disclosure, an air curtain structure is surrounded a cabin, so that the air curtain structure sends dry air from its plurality of openings, thereby reducing ambient humidity and keeping the surface of the cabin dry and free of moisture, which can not only save the manpower and time required to manually shut down the machine and heat the outside the cabin at specific operating times to evaporate condensation water, but also avoid the problem that condensation water dropped to damage the test equipment.

### BRIEF DESCRIPTION OF THE DRAWINGS

FIG. 1 is a schematic view of a conventional test equipment.

FIG. 2 is a schematic view of a test equipment of the present disclosure.

FIG. 3 is a schematic view of an air curtain structure of the present disclosure applied to a test equipment.

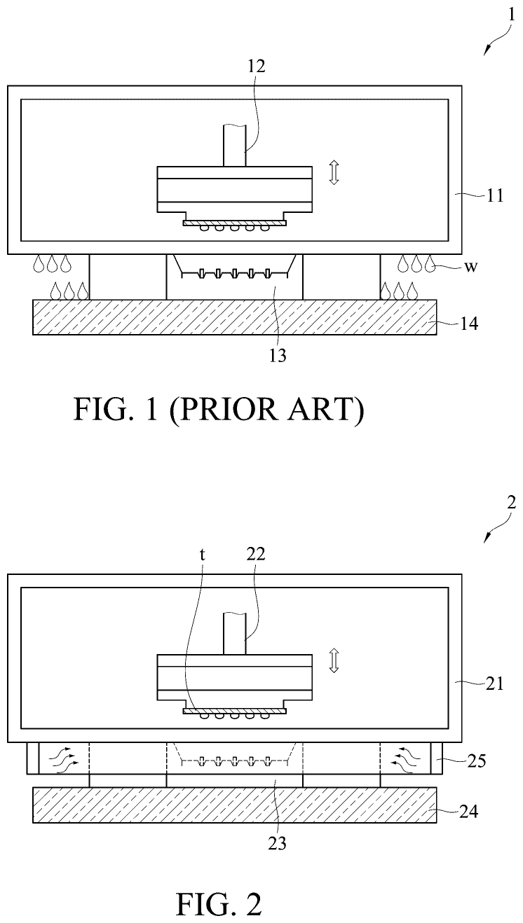

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” and the like are for illustrative purposes, and are not meant to limit the scope in which the present disclosure can be implemented. Any variations or modifications to their relative relationships, without substantially changes in the technical content, are also to be construed as within the scope implementable by the present disclosure.

FIG. 2 is a schematic view of a test equipment 2 of the present disclosure, the test equipment 2 comprises a cabin 21, a pick-and-place device 22, a test base body 23, an electronic carrier 24 and an air curtain structure 25.

The cabin 21 is used to provide a low test environment, such as 0˜−65 degrees Celsius.

The pick-and-place device 22 is for example a robotic arm, used to move the element under test t into the cabin 21, for instance, the element under test t are moved into the cabin 21 by picking/absorbing and the like to conduct electrical testing according to the test environment. The element under test t is electronic element such as active element, passive element, or package modules.

The test base body 23 is connected to the cabin 21 for connecting/testing the element under test t.

The electronic carrier 24 is connected to the test base body 23 for receiving test information.

The air curtain structure 25 is disposed surrounding the cabin 21 to output fluid toward the cabin 21. The air curtain structure 25 can be placed between the cabin 21 and the electronic carrier 24, for instance, the air curtain structure 25 can be fixed to the side of the test base body 23 or the outer surface of the cabin 21.

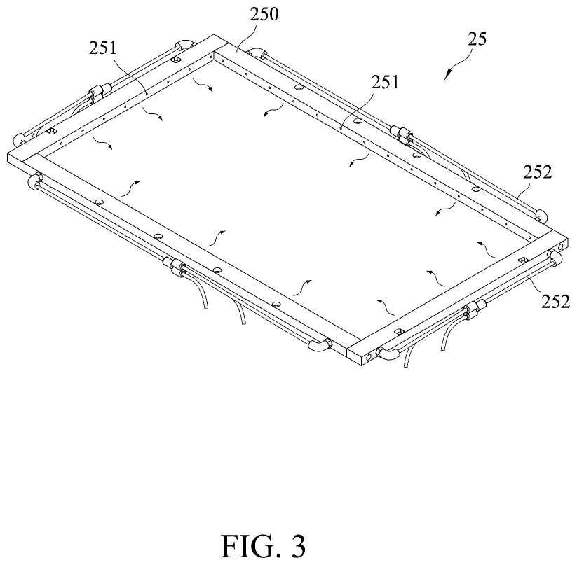

Please also refer to FIG. 3, the air curtain structure 25 includes a ring body 250 and a plurality of openings 251 disposed on the ring body. The ring body 250 is hollow for the fluid flowing therethrough. The plurality of openings 251 are disposed inside the ring body 250 for the fluid to be ejected outward from inside the ring body 250. In addition, a plurality of pipelines 252 are connected to the outside of the ring body 250 to allow providing fluid to the ring body 250 from outside and eject it outward through the plurality of openings 251.

In an embodiment, the ring body 250 is rectangular and its overall dimension (length, weight and height) is about 30 (length)*15(weight)*4(height) cm³. The plurality of openings 251 are disposed inside the ring body 250, and the diameter of each opening 251 is about 1.5˜3 mm. In addition, the direction of the plurality of openings 251 can tilted upward, so that the fluid is blown outward at an angle of about 10˜45 degrees. Furthermore, the flow rate of the fluid is about 20˜40 L/min. The above embodiments are only for illustration and are not intended to limit the present disclosure, an adjustment according to the actual on-site ambient temperature and the dimension of the test equipment is needed.

In actual application, the pick-and-place device 22 is used to pick up the element under test t into the cabin 21, and the element under test t are connected to the test base body 23 for conducting electrical testing. Since the test temperature inside the cabin 21 is tens of degrees Celsius below zero (for instance −35˜−65 degrees), while the room temperature outside the cabin 21 is about 22˜25 degrees Celsius. Therefore, during the test process, due to the large temperature difference between the inside and the outside of the cabin, condensation water may occur on the outer wall surface (particularly the bottom surface) of the cabin 21. At this time, dry air is blown out from the plurality of openings 251 through the air curtain structure 25 surrounding the periphery of the cabin 21, thereby reducing the ambient humidity and keeping the surface of the cabin 21 dry and free of moisture to avoid the conventional problem that condensation water dropped to damage the equipment.

In view of the above, in the test equipment of the present disclosure, an air curtain structure is surrounding a cabin, so that the air curtain structure sends dry air from its plurality of openings, thereby reducing ambient humidity and keeping the surface of the cabin dry and free of moisture, which can not only save time that is customary to manually shut down the machine and heat up outside the cabin at specific operated times, so as to save the waste of manpower and time required to evaporate condensation water, and further to avoid the problem that condensation water dropped to damage the test equipment.

The above embodiments are provided for illustrate the principles of the present disclosure and it technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A test equipment, comprising:
a cabin providing a low-temperature testing environment for an element under test;
a pick-and-place device for moving the element under test into the cabin;
a test base body connected to the cabin for testing the element under test;
an electronic carrier connected to the test base body for receiving test information; and
an air curtain structure surrounding the cabin to output fluid toward the cabin.

2. The test equipment of claim 1, wherein the pick-and-place device is a robotic arm.

3. The test equipment of claim 1, wherein the element under test is an electronic element.

4. The test equipment of claim 1, wherein the air curtain structure is fixed to a side of the test base body or an outer surface of the cabin.

5. The test equipment of claim 1, wherein the air curtain structure includes a ring body and a plurality of openings formed inside the ring body, and the ring body is hollow for the fluid being output from inside the ring body toward the cabin to outside through the plurality of openings.

6. The test equipment of claim 5, wherein a plurality of pipelines are connected to the outside of the ring body to allow providing fluid to the ring body from outside.

7. The test equipment of claim 5, wherein a direction of the plurality of openings is tilting upward to output the fluid.

8. An air curtain structure, applied to a test equipment with a cabin for providing a low-temperature testing environment for an element under test, the air curtain structure comprising:
a ring body surrounding the cabin, and the ring body being hollow for fluid flowing therethrough; and
a plurality of openings disposed inside the ring body for the fluid being output from inside the ring body toward the cabin to outside.

9. The air curtain structure of claim 8, wherein a plurality of pipelines are connected to the outside of the ring body to allow providing fluid to the ring body from outside.

10. The air curtain structure of claim 8, wherein a direction of the plurality of openings is tilting upward to output the fluid.
